(19) United States
(12) Patent Application Publication
(10) Pub. No.: US 2018/0219524 A1
(43) Pub. Date: Aug. 2, 2018

(54) DYNAMIC IMPEDANCE MANAGEMENT

(71) Applicant: QUALCOMM Incorporated, San Diego, CA (US)

(72) Inventor: Arvind Govindaraj, San Diego, CA (US)

(21) Appl. No.: 15/423,395

(22) Filed: Feb. 2, 2017

(51) Int. Cl. H03H 7/38; H02J 50/12; H02J 5/00

(52) U.S. Cl. CPC H03H 7/38; H02J 5/005; H02J 50/12

(57) ABSTRACT

A wireless power receiver includes: a power-receiving antenna configured to receive power wirelessly from a transmitter; power-processing circuitry that is coupled to the power-receiving antenna to receive power from the power-receiving antenna and that is configured to process the power received from the power-receiving antenna; and a controller communicatively coupled to the power-processing circuitry and configured to: determine a value of a dynamic parameter indicative of at least one of content of the power-processing circuitry, operation of the power-processing circuitry, or a relationship between the receiver and the transmitter; and determine an estimated impedance using the value of the dynamic parameter, the estimated impedance being an estimate of at least a portion of reflected impedance presented to the transmitter by the receiver.

### TECHNICAL FIELD

The disclosure relates generally to wireless power delivery to electronic devices, and in particular to management of an impedance presented to a transmitter by a receiver.

### BACKGROUND

An increasing number and variety of electronic devices are powered via rechargeable batteries. Such devices include mobile phones, portable music players, laptop computers, tablet computers, computer peripheral devices, communication devices (e.g., BLUETOOTH devices), digital cameras, hearing aids, and the like. While battery technology has improved, battery-powered electronic devices increasingly require and consume greater amounts of power. As such, these devices frequently require recharging. Rechargeable devices are often charged via wired connections that require cables or other similar connectors that are physically connected to a power supply. Cables and similar connectors may sometimes be inconvenient or cumbersome and have other drawbacks. Wireless power charging systems may allow users to charge and/or power electronic devices without physical, electro-mechanical connections, thus simplifying the use of the electronic device.

Devices providing power wirelessly typically use resonant power amplifiers that are efficient over a specified range of load impedance which corresponds to the impedances of receivers for receiving power wirelessly. Consequently, specifications are often provided for the impedances of receivers that various transmitters of wireless power can support efficiently. Dynamic impedance changes of a receiver may cause the power amplifier of the transmitter to operate outside of the power amplifier's efficient range.

### SUMMARY

The following description and accompanying drawings provide a better understanding of the nature and advantages of the disclosure.

An example of a wireless power receiver includes: a power-receiving antenna configured to receive power wirelessly from a transmitter; power-processing circuitry that is coupled to the power-receiving antenna to receive power from the power-receiving antenna and that is configured to process the power received from the power-receiving antenna; and a controller communicatively coupled to the power-processing circuitry and configured to: determine a value of a dynamic parameter indicative of at least one of content of the power-processing circuitry, operation of the power-processing circuitry, or a relationship between the receiver and the transmitter; and determine an estimated impedance using the value of the dynamic parameter, the estimated impedance being an estimate of at least a portion of reflected impedance presented to the transmitter by the receiver.

An example of a method of estimating impedance of a wireless power receiver includes: receiving power wirelessly from a transmitter by a receiver, the power received being received power; processing the received power to produce output power; determining a value of a dynamic parameter indicative of at least one of circuit content of the receiver, the processing of the received power, or a relationship between the receiver and the transmitter; and determining an estimated impedance using the value of the dynamic parameter, the estimated impedance being an estimate of a reflected impedance presented to the transmitter by the receiver.

An example of a non-transitory, processor-readable storage medium includes processor-readable instructions configured to cause a processor to: determine a value of a dynamic parameter indicative of at least one of content of a receiver, operation of the receiver, or a relationship of the receiver and a transmitter; and determine an estimated impedance using the value of the dynamic parameter, the estimated impedance being an estimate of a reflected impedance presented to the transmitter by the receiver.

Another example of a wireless power receiver includes: power-receiving means for receiving power wirelessly from a transmitter; processing means, coupled to the power-receiving, for processing power received from the power-receiving means to produce output power; means for determining a value of a dynamic parameter indicative of at least one of content of the processing means, operation of the processing means, or a relationship between the receiver and the transmitter; and means for determining an estimated impedance using the value of the dynamic parameter, the estimated impedance being an estimate of a reflected impedance presented to the transmitter by the receiver.

### BRIEF DESCRIPTION OF THE DRAWINGS

Drawing elements that are common among the following figures may be identified using the same reference numerals.

With respect to the discussion to follow and in particular to the drawings, the particulars shown represent examples for purposes of illustrative discussion, and are presented in the cause of providing a description of principles and conceptual aspects of the disclosure. In this regard, no attempt is made to show implementation details beyond what is needed for a fundamental understanding of the disclosure. The discussion to follow, in conjunction with the drawings, makes apparent to those of skill in the art how embodiments in accordance with the disclosure may be practiced.

FIG. 1 is a functional block diagram of an example of a wireless power transfer system.

FIG. 2 is a functional block diagram of an example of another wireless power transfer system.

FIG. 3 is a schematic diagram of an example of a portion of transmit circuitry or receive circuitry of the system shown in FIG. 2.

FIG. 4 is a block diagram of components of a receiver for receiving power wirelessly.

FIG. 5 is a simplified diagram of a transmitter shown in FIG. 2 and an impedance seen by the transmitter.

FIG. 6 is a block diagram of components of a controller shown in FIG. 4.

FIG. 7 is an example of a linearized circuit model of a portion of a receiver shown in FIG. 4.

FIG. 8 is a diagram of curve fit plots of resistance as a function of load power for various values of DC rectified voltage.

FIG. 9 is a diagram of curve fit plots of reactance as a function of load power for various values of DC rectified voltage.

FIG. 10 is a diagram of a relationship between a reflected reactance and DC rectified voltage.

FIG. 11 is a diagram of reflected reactance as a function of load power.

FIG. 12 is a block flow diagram of a method of estimating a reflected impedance.

FIG. 13 is a block flow diagram of a method of attempting to tune reflected receiver impedance to within an acceptable range.

### DETAILED DESCRIPTION

Wireless power transfer may refer to transferring any form of energy associated with electric fields, magnetic fields, electromagnetic fields, or otherwise from a transmitter to a receiver without physical electrical conductors attached to and connecting the transmitter to the receiver to deliver the power (e.g., power may be transferred through free space). The power output into a wireless field (e.g., a magnetic field or an electromagnetic field) may be received, captured by, or coupled to by a power receiving element to achieve power transfer. The transmitter transfers power to the receiver through a wireless coupling of the transmitter and receiver.

Techniques are discussed herein for managing reflected impedance provided to a wireless-power transmitter by a wireless-power receiver. For example, a receiver may apply values of one or more dynamic variables to a model of the receiver to determine impedance values of the receiver. The receiver may further use the determined impedance values, and a value of mutual coupling between the receiver and the transmitter, to determine an estimated reflected impedance presented to the transmitter by the receiver. The receiver may use a specified range of reflected impedances to adjust one or more dynamic parameter values to try to move the reflected impedance into, or keep the reflected impedance in, the specified range. For example, the receiver may adjust a tuning capacitance, a tuning inductance, and/or operational parameters of a rectifier (including phase and/or duty cycle). The specified range may be known by the receiver before interaction with the transmitter and/or may be obtained by the receiver upon interaction with the transmitter (e.g., from the transmitter itself and/or from a third party). The specified range may change over time, e.g., in response to multiple receivers affecting a total impedance seen by the transmitter due to the receivers (e.g., due to the quantity and/or proximities and/or types and/or impedances of the receivers changing).

Items and/or techniques described herein may provide one or more of the following capabilities, as well as other capabilities not mentioned. Efficient operation of a wireless-power transmitter may be maintained despite changes in quantities, types, and/or individual impedances of one or more receivers receiving power wirelessly from the transmitter. Stability of wireless power transfer systems may be improved, particularly in multiple receiver systems. Wireless power transfer to receivers in multiple-receiver situations may be improved. Wireless power transmitter design may be simplified. Compatibility of wireless power transmitters and wireless power receivers may be improved. Other capabilities may be provided and not every implementation according to the disclosure must provide any, let alone all, of the capabilities discussed. Further, it may be possible for an effect noted above to be achieved by means other than that noted, and a noted item/technique may not necessarily yield the noted effect.

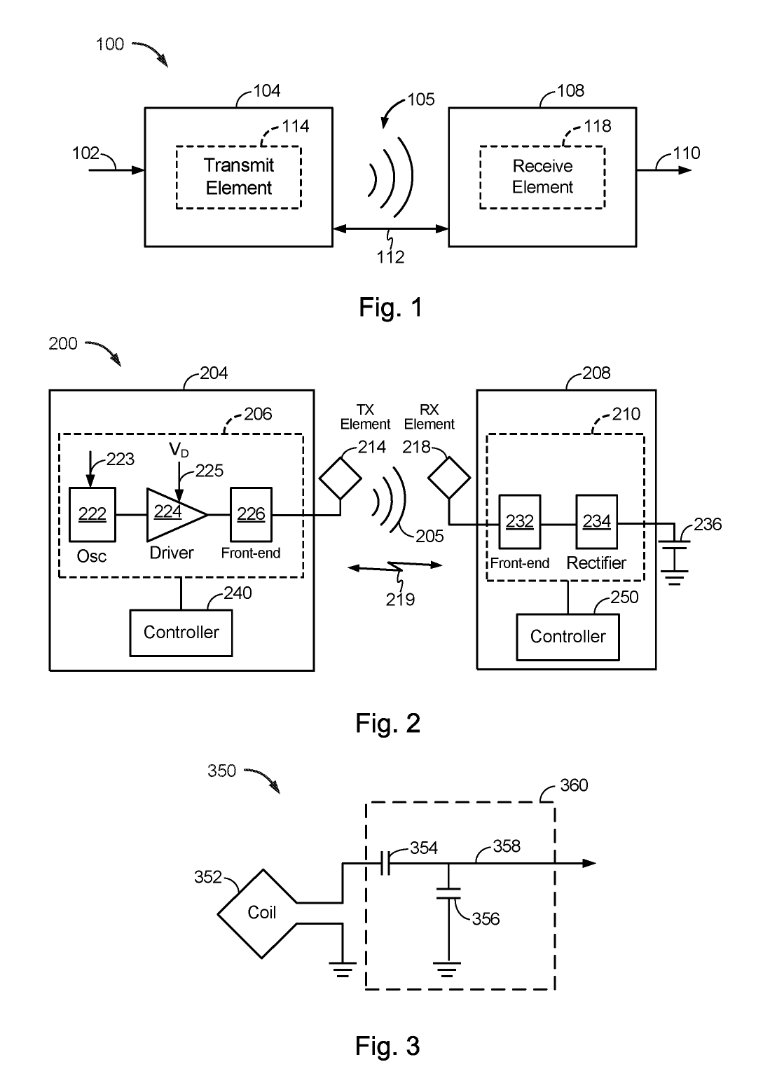

FIG. 1 is a functional block diagram of an example of a wireless power transfer system 100. Input power 102 may be provided to a transmitter 104 from a power source (not shown in this figure) to generate a wireless (e.g., magnetic or electromagnetic) field 105 for performing energy transfer. A receiver 108 may couple to the wireless field 105 and generate output power 110 for storing or consumption by a device (not shown in this figure) that is coupled to receive the output power 110. The transmitter 104 and the receiver 108 are separated by a non-zero distance 112. The transmitter 104 includes a power transmitting element 114 configured to transmit/couple energy to the receiver 108. The receiver 108 includes a power receiving element 118 configured to receive or capture/couple energy transmitted from the transmitter 104.

The transmitter 104 and the receiver 108 may be configured according to a mutual resonant relationship. When the resonant frequency of the receiver 108 and the resonant frequency of the transmitter 104 are substantially the same, transmission losses between the transmitter 104 and the receiver 108 are reduced compared to the resonant frequencies not being substantially the same. As such, wireless power transfer may be provided over larger distances when the resonant frequencies are substantially the same. Resonant inductive coupling techniques allow for improved efficiency and power transfer over various distances and with a variety of inductive power transmitting and receiving element configurations.

The wireless field 105 may correspond to the near field of the transmitter 104. The near field corresponds to a region in which there are strong reactive fields resulting from currents and charges in the power transmitting element 114 that do not significantly radiate power away from the power transmitting element 114. The near field may correspond to a region that up to about one wavelength, of the power transmitting element 114. Efficient energy transfer may occur by coupling a large portion of the energy in the wireless field 105 to the power receiving element 118 rather than propagating most of the energy in an electromagnetic wave to the far field.

The transmitter 104 may output a time-varying magnetic (or electromagnetic) field with a frequency corresponding to the resonant frequency of the power transmitting element 114. When the receiver 108 is within the wireless field 105, the time-varying magnetic (or electromagnetic) field may induce a voltage in the power receiving element 118. As described above, with the power receiving element 118 configured as a resonant circuit to resonate at the frequency of the power transmitting element 114, energy may be efficiently transferred. An alternating current (AC) voltage signal induced in the power receiving element 118 may be rectified to produce a direct current (DC) voltage signal that may be provided to charge an energy storage device (e.g., a battery) or to power a load.

FIG. 2 is a functional block diagram of an example of a wireless power transfer system 200. The system 200 includes a transmitter 204 and a receiver 208. The transmitter 204 (also referred to herein as power transmitting unit, PTU) is configured to provide power to a power transmitting element 214 that is configured to transmit power wirelessly to a power receiving element 218 that is configured to receive power from the power transmitting element 214 and to provide power to the receiver 208. Despite their names, the power transmitting element 214 and the power receiving element 218, being passive elements, may transmit and receive power and communications.

The transmitter 204 includes the power transmitting element 214, transmit circuitry 206 that includes an oscillator 222, a driver circuit 224, and a front-end circuit 226. The power transmitting element 214 is shown outside the transmitter 204 to facilitate illustration of wireless power transfer using the power receiving element 218. The oscillator 222 may be configured to generate an oscillator signal at a desired frequency that may adjust in response to a frequency control signal 223. The oscillator 222 may provide the oscillator signal to the driver circuit 224. The driver circuit 224 may be configured to drive the power transmitting element 214 at, for example, a resonant frequency of the power transmitting element 214 based on an input voltage signal (VD) 225. The driver circuit 224 may be a switching amplifier configured to receive a square wave from the oscillator 222 and output a sine wave.

The front-end circuit 226 may include a filter circuit configured to filter out harmonics or other unwanted frequencies. The front-end circuit 226 may include a matching circuit configured to match the impedance of the transmitter 204 to the impedance of the power transmitting element 214. As will be explained in more detail below, the front-end circuit 226 may include a tuning circuit to create a resonant circuit with the power transmitting element 214. As a result of driving the power transmitting element 214, the power transmitting element 214 may generate a wireless field 205 to wirelessly output power at a level sufficient for charging a battery 236, or powering a load.

The transmitter 204 further includes a controller 240 operably coupled to the transmit circuitry 206 and configured to control one or more aspects of the transmit circuitry 206, or accomplish other operations relevant to managing the transfer of power. The controller 240 may be a micro-controller or a processor. The controller 240 may be implemented as an application-specific integrated circuit (ASIC). The controller 240 may be operably connected, directly or indirectly, to each component of the transmit circuitry 206. The controller 240 may be further configured to receive information from each of the components of the transmit circuitry 206 and perform calculations based on the received information. The controller 240 may be configured to generate control signals (e.g., signal 223) for each of the components that may adjust the operation of that component. As such, the controller 240 may be configured to adjust or manage the power transfer based on a result of the operations performed by the controller 240. The transmitter 204 may further include a memory (not shown) configured to store data, for example, such as instructions for causing the controller 240 to perform particular functions, such as those related to management of wireless power transfer.

The receiver 208 (also referred to herein as power receiving unit, PRU) includes the power receiving element 218, and receive circuitry 210 that includes a front-end circuit 232 and a rectifier circuit 234. The power receiving element 218 is shown outside the receiver 208 to facilitate illustration of wireless power transfer using the power receiving element 218. The front-end circuit 232 may include matching circuitry configured to match the impedance of the receive circuitry 210 to the impedance of the power receiving element 218. As will be explained below, the front-end circuit 232 may further include a tuning circuit which is capable of adjusting the impedance of the receiver around the point of resonance. The rectifier circuit 234 may generate a DC power output from an AC power input to charge the battery 236, as shown in FIG. 2. The receiver 208 and the transmitter 204 may additionally communicate on a separate communication channel 219 (e.g., BLUETOOTH, ZIGBEE, cellular, etc.). The receiver 208 and the transmitter 204 may alternatively communicate via in-band signaling using characteristics of the wireless field 205.

The receiver 208 may be configured to determine whether an amount of power transmitted by the transmitter 204 and received by the receiver 208 is appropriate for charging the battery 236. The transmitter 204 may be configured to generate a predominantly non-radiative field with a direct field coupling coefficient (k) for providing energy transfer. The receiver 208 may directly couple to the wireless field 205 and may generate an output power for storing or consumption by a battery (or load) 236 coupled to the output or receive circuitry 210.

The receiver 208 further includes a controller 250 that may be configured similarly to the transmit controller 240 as described above for managing one or more aspects of the wireless power receiver 208. The receiver 208 may further include a memory (not shown) configured to store data, for example, such as instructions for causing the controller 250 to perform particular functions, such as those related to management of wireless power transfer.

As discussed above, transmitter 204 and receiver 208 may be separated by a distance and may be configured according to a mutual resonant relationship to try to minimize transmission losses between the transmitter 204 and the receiver 208.

FIG. 3 is a schematic diagram of an example of a portion of the transmit circuitry 206 or the receive circuitry 210 of FIG. 2. While a coil, and thus an inductive system, is shown in FIG. 3, other types of systems, such as capacitive systems for coupling power, may be used, with the coil replaced with an appropriate power transfer (e.g., transmit and/or receive) element. As illustrated in FIG. 3, transmit or receive circuitry 350 includes a power transmitting or receiving element 352 and a tuning circuit 360. The power transmitting or receiving element 352 may also be referred to or be configured as an antenna such as a “loop” antenna. The term “antenna” generally refers to a component that may wirelessly output energy for reception by another antenna and that may receive wireless energy from another antenna. The power transmitting or receiving element 352 may also be referred to herein or be configured as a “magnetic” antenna, such as an induction coil (as shown), a resonator, or a portion of a resonator. The power transmitting or receiving element 352 may also be referred to as a coil or resonator of a type that is configured to wirelessly output or receive power. As used herein, the power transmitting or receiving element 352 is an example of a “power transfer component” of a type that is configured to wirelessly output and/or receive power. The power transmitting or receiving element 352 may include an air core or a physical core such as a ferrite core (not shown).

When the power transmitting or receiving element 352 is configured as a resonant circuit or resonator with tuning circuit 360, the resonant frequency of the power transmitting or receiving element 352 may be based on the inductance and capacitance. Inductance may be simply the inductance created by a coil and/or other inductor forming the power transmitting or receiving element 352. Capacitance (e.g., a capacitor) may be provided by the tuning circuit 360 to create a resonant structure at a desired resonant frequency. As a non-limiting example, the tuning circuit 360 may comprise a capacitor 354 and a capacitor 356, which may be added to the transmit or receive circuitry 350 to create a resonant circuit.

The tuning circuit 360 may include other components to form a resonant circuit with the power transmitting or receiving element 352. As another non-limiting example, the tuning circuit 360 may include a capacitor (not shown) placed in parallel between the two terminals of the circuitry 350. Still other designs are possible. For example, the tuning circuit in the front-end circuit 226 may have the same design (e.g., 360) as the tuning circuit in the front-end circuit 232. Alternatively, the front-end circuit 226 may use a tuning circuit design different than in the front-end circuit 232.

For power transmitting elements, the signal 358, with a frequency that substantially corresponds to the resonant frequency of the power transmitting or receiving element 352, may be an input to the power transmitting or receiving element 352. For power receiving elements, the signal 358, with a frequency that substantially corresponds to the resonant frequency of the power transmitting or receiving element 352, may be an output from the power transmitting or receiving element 352. Although aspects disclosed herein may be generally directed to resonant wireless power transfer, persons of ordinary skill will appreciate that aspects disclosed herein may be used in non-resonant implementations for wireless power transfer.

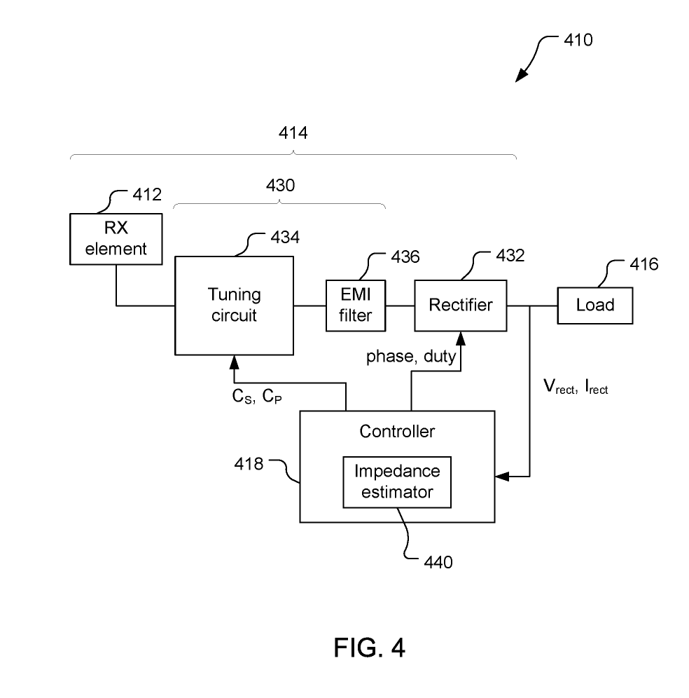

Referring to FIG. 4, with further reference to FIGS. 1-3, a receiver 410, which is an example of the receiver 108 shown in FIG. 1, includes power-processing circuitry 414, a load 416, and a controller 418. The receiver 410 is a power receiver capable of receiving power wirelessly from a transmitter. The power-processing circuitry 414 includes a power receiving element 412, a front-end circuit 430, and a rectifier 432. The power receiving element 412 may be a coil or other form of antenna for receiving power from a transmitter such as the transmitter 104 shown in FIG. 1. The front-end circuit 430 is an example of the front-end circuit 232 shown in FIG. 2, and the rectifier 432, e.g., a controlled synchronous rectifier, is an example of the rectifier 234 shown in FIG. 2. The front-end circuit 430 includes a tuning circuit 434 and an electromagnetic interference (EMI) filter 436. The controller 418 is communicatively coupled to the tuning circuit and to the rectifier 432. The receiver 410 is configured to receive power wirelessly, to estimate an impedance presented by the receiver 410 to a transmitter, and to change the impedance presented to the transmitter, e.g., to try to have the impedance presented to the transmitter be within a desired range. The receiver 410 is configured to change the impedance toward, or to retain the impedance in, the desired range, e.g., a specified impedance range.

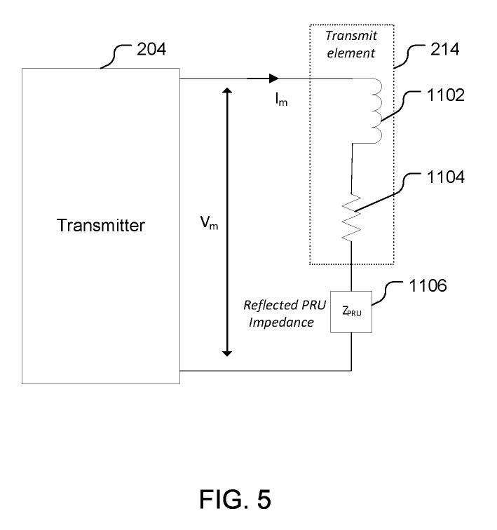

The receiver 410 presents a reflected impedance in the presence of a wireless-power transmitter, e.g., on a power-charging surface of a charge pad. As shown in FIG. 5, an impedance (Vₘ/Iₘ) seen by the transmitter 204 can be represented as an impedance of the transmit element 214 (that includes an inductance 1102 and a resistance 1104) and a reflected impedance 1106 from the receiver 410. The reflected impedance is labeled Z_{PRU} and an expression for this impedance is provided and discussed below. The reflected impedance comprises a static impedance and a dynamic impedance. The dynamic impedance is a function of electrical operation of the receiver 410 including operation of the tuning circuit 434 and/or the rectifier 432 and/or the load 416 (with the load 416 itself possibly dynamically changing). The static impedance is a function of device construction of the receiver 410, e.g., the amount and type of metal present in the receiver 410. The transmitter, e.g., the transmitter 204 is configured to measure the static impedance of the receiver 410 and to communicate this static impedance to the receiver 410.

The tuning circuit 434 is a controllable impedance network configured to change an input impedance of the receiver 410, and thus a reflected impedance of the receiver 410 that is presented to a wireless-power transmitter (referred to herein as a transmitter for simplicity). For example, the tuning circuit 434 may include one or more variable-impedance elements such as one or more switched capacitors, one or more variable capacitors, one or more switched inductors, and/or one or more variable inductors. Any of these variable-impedance elements may be series connected or parallel-connected. Operation of the variable-impedance element(s) affects the dynamic impedance portion of the reflected impedance of the receiver 410. The tuning circuit 434 is configured to respond to one or more control signals from the controller 418 to set the value(s) of the variable-impedance element(s). For example, as shown in FIG. 4, the tuning circuit 434 is configured to receive, from the controller 418, a series-connected capacitor control signal indicative of a series-connected capacitance value C_{S} and a parallel-connected capacitor control signal indicative of a parallel-connected capacitance value C_{P} and to respond to these signals by setting the value of a series-connected variable capacitor and the value of a parallel-connected variable capacitor, respectively, and/or by selecting/de-selecting to use a series-connected switched capacitor or a parallel-connected switched capacitor, respectively.

Operation of the rectifier 432 also affects the dynamic portion of the impedance of the receiver 410. Changes in power delivered by the rectifier 432, changes in phase and duty cycle of the rectifier 432, and changes in topology of the rectifier 432 (i.e., controlling switches of the rectifier 432 to implement different effects, e.g., full bridge/doubler) affect the reflected impedance presented to the transmitter. Further, changes in power consumed by the rectifier 432 may also affect the reflected impedance presented to the transmitter.

For an inductive coupling between the transmitter and the receiver 410, the reflected impedance of the receiver 410 presented to the transmitter may be expressed by the following equation

Z_{PRU}Zₛ+ω²M²(R_{L}+Z_{T}) Eqn. (1)

In Equation (1), Zₛ is the static impedance of the receiver 410, ω is 2πf (where f is frequency of power transmission, e.g., a resonant frequency of a transmitter), M is mutual coupling between the transmitter and the receiver 410, R_{L} is the effective resistance of the load 416, and Z_{T} is the impedance of the receiver circuit 414.

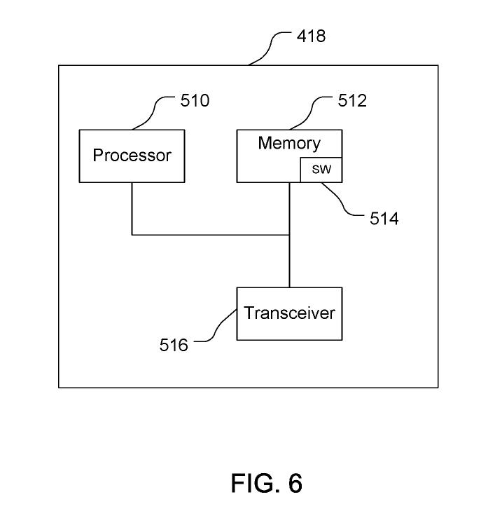

Referring to FIG. 6, with further reference to FIG. 4, the controller 418 comprises a computer system including a processor 510, a memory 512 including software (SW) 514, and a transceiver 516. The processor 510 is preferably an intelligent hardware device, for example a central processing unit (CPU) such as those made or designed by QUALCOMM®, ARM®, Intel® Corporation, or AMD®, a microcontroller, an application specific integrated circuit (ASIC), etc. The processor 510 may comprise multiple separate physical entities that can be distributed in the controller 418. The memory 512 may include random access memory (RAM) and/or read-only memory (ROM). The memory 512 is a non-transitory, processor-readable storage medium that stores the software 514 which is processor-readable, processor-executable software code containing instructions that are configured to, when performed, cause the processor 510 to perform various functions described herein. The description may refer only to the processor 510, or the controller 418 more generally, performing the functions, but this includes other implementations such as where the processor 510 executes software and/or firmware. The software 514 may not be directly executable by the processor 510 and instead may be configured to, for example when compiled and executed, cause the processor 510 to perform the functions. Whether needing compiling or not, the software 514 contains the instructions to cause the processor 510 to perform the functions. The processor 510 is communicatively coupled to the memory 512. The processor 510 in combination with the memory 512, and/or the transceiver 518 provide means for performing functions as described herein. For example, the processor 510 and the memory 512 may implement an impedance estimator 440 discussed below. The software 514 can be loaded onto the memory 512 by being downloaded via a network connection, uploaded from a disk, etc. The transceiver 516 is configured to communicate wirelessly using the power receiving element 412 for in-band communications and/or another antenna (not shown) for out-of-band communications.

Referring again to FIG. 4, with further reference to FIG. 6, the controller 418 provides values of dynamic variables to the tuning circuit 434 and the rectifier 432, and includes the impedance estimator 440. The controller 418 is configured to set and provide the series-connected capacitance value C_{S} and/or the parallel-connected capacitance value C_{P} to the tuning circuit 434 to tune the tuning circuit 434 for receiving power from the transmitter 204. The controller 418 is further configured to set and provide a phase value and a duty cycle value to the rectifier 432 to adjust how the rectifier 432 rectifies received power from the transmitter 204. The impedance estimator 440 is configured to estimate the reflected impedance presented to the transmitter by the receiver 410. In particular, the impedance estimator 440 is configured to determine the reflected impedance according to Equation (1). The impedance estimator 440 is configured to determine the values of the components of Equation (1) from formulas based on linearized models of the power receiving element 412 and the front-end circuit 430, and the rectifier 432, using the dynamic parameter values set and provided by the controller 418. Thus, the values of ω, M, R_{L}, and Z_{T} are also dynamic parameters themselves. The dynamic parameters consequently may be indicative of content of the receiver (e.g., one or more components of the receiver 410 and/or the dynamic impedance of the receiver 410), operation of the receiver 410 (e.g., the frequency of power received by the receiver 410 from the transmitter), or a relationship between the receiver 410 and the transmitter (e.g., the mutual coupling M), or a combination of these. The impedance estimator 440 is configured to estimate the reflected impedance using the values of dynamic parameters.

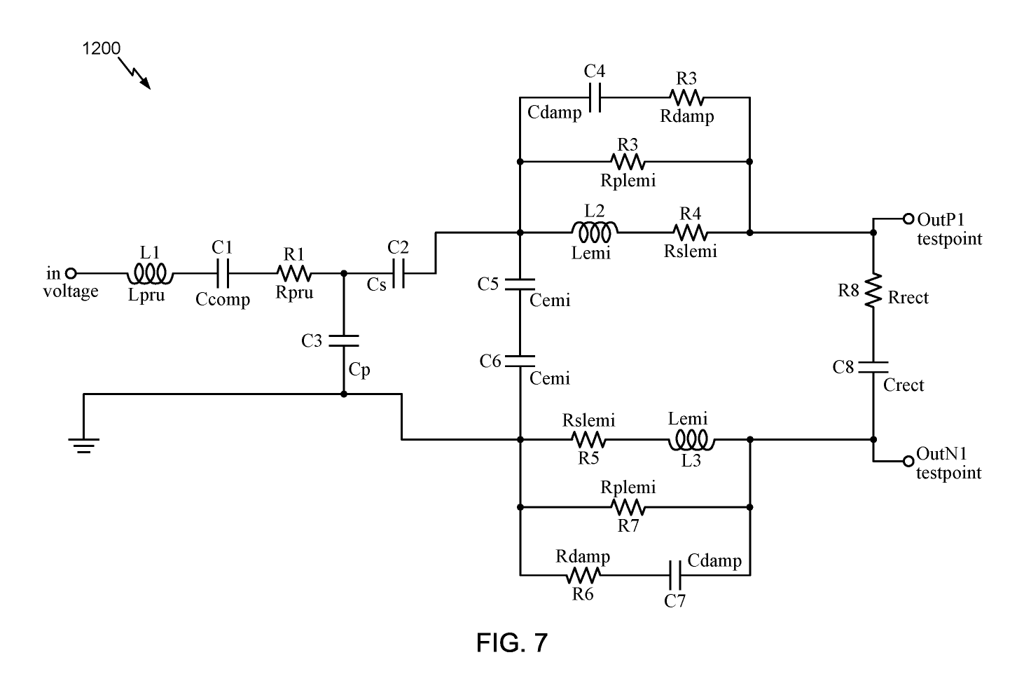

The impedance estimator 440 is preferably configured to evaluate a model of the power receiving element 412 and the front-end circuit 430 of the power-processing circuitry 414. The model is a representation of the receiving element 412 and the front-end circuit 430, e.g., as a circuit of discrete values, that can be used to determine (e.g., calculate or look up) reflected impedance values for different situations such as different circuit component values and/or different operation conditions. The model is preferably a linearized model that represents the power receiving element 412 and the front-end circuit 430. An example linearized circuit model 1200 is shown in FIG. 7. The model 1200 provides a simplified circuit of discrete components the values of which may be altered to reflect a present state (e.g., configuration and/or operation) of the receive element 412 and the front-end circuit 430. The model, e.g., the model 1200, may provide a circuit that may be evaluated in accordance with known circuit analysis techniques to determine an impedance, or may be a table of impedance values corresponding to one or more dynamic parameter values, or may be an equation for impedance as a function of one or more dynamic parameter values. If the model is a table of impedances, then the impedance estimator 440 may interpolate between impedance values for values of the dynamic parameter(s) not provided in the table. Preferably, the model provides a parameterized Thevenin model with a simple equation for a lumped impedance. The model can include switched and/or variable impedances (e.g., switched and/or variable capacitance(s) and/or inductance(s)) that can be used to adjust the tuning of the tuning circuit 434. The associated equation can include one or more dynamic parameters indicative of such impedance(s) for the Thevenin equivalent. For example, a Thevenin impedance Zₜₕ may be a function of a series-connected capacitance value C_{S} and a parallel-connected capacitance value C_{P}, i.e., Zₜₕ=f(C_{S}, C_{P}), with C_{S} and C_{P} being dynamic parameters set by, and thus known by, the controller 418. Also or alternatively, a full linear model (as opposed to the simplified Thevenin equation) may be computed in real time as the full linear model has low computational complexity. If both the simplified Thevenin impedance and the full linear model are computed, the impedances from both of these computations may be combined, e.g., averaged. The model 1200 includes a resistor R_{rec}t and a capacitor C_{rect} representative of the rectifier 432.

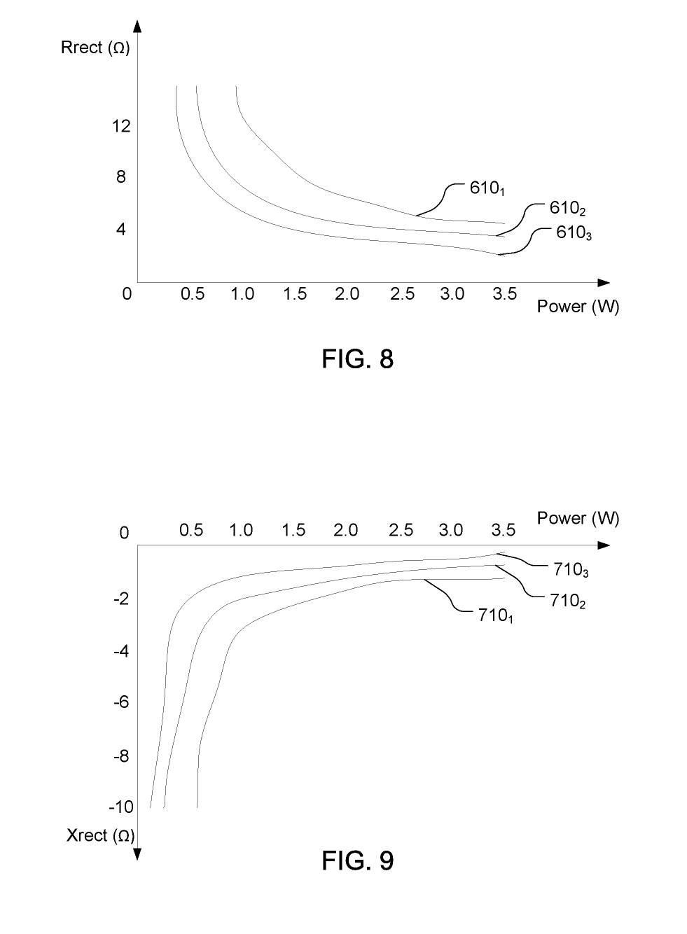

The impedance estimator 440 is preferably also configured to evaluate a model of the rectifier 432. The model is preferably a linearized model that represents the rectifier 432. The model may provide a circuit that may be evaluated in accordance with known circuit analysis techniques to determine an impedance, or may be a table of impedance values corresponding to one or more dynamic parameter values, or may be an equation for impedance as a function of one or more dynamic parameter values. If the model is a table of impedances, then the impedance estimator 440 may interpolate between impedance values for values of the dynamic parameter(s) not provided in the table. Preferably, an AC (alternating current) model of the rectifier 432 may be simplified to relationships as a function of rectified DC (direct current) voltage V_{rect}, DC load power (as indicated by V_{rect} and rectified DC current I_{rect}), and control variables such as a phase and/or a duty cycle of the rectifier 432. For example, the model for the impedance of the rectifier 432 may be generated using SPICE simulations of circuit measurements. For example, as shown in FIGS. 8-9, these simulations may yield resistance plots 610₁₋₃ and reactance plots 710₁₋₃ as a function of DC load power for each of three different values of rectified DC voltage V_{rect}. Only three resistance plots 610₁₋₃ and three reactance plots 710₁₋₃ are shown for simplicity, but data for more values of DC rectified voltage using the simulation would preferably be produced. The values of the resistance and reactance for the various values of DC rectified voltage as a function of DC load power may be stored in look-up tables, e.g., in the memory 512, that may be accessed by the impedance estimator 440 for use in determining the impedance of the receiver 410, e.g., by combining a looked-up impedance of the rectifier 432 with a calculated impedance of the front-end circuit 430 and the power receiving element 412. The linearized rectifier model can also be represented using curve fit equations which can be computed along with the linear model of the rest of the receiver 410. For example, the following are examples of curve-fit equations for the linearized model:

For V_{rect}=4.2V:

R_{rect}=−33417·(−1.98637+x)(−1.76398+x)(−1.57329+x)(1.69067−2.59024x+x²)(0.922424−1.85645x+x²)(0.41244−1.13913x+x²)(0.138209−0.539539x+x²)(0.0255988−0.139947x+x²) Eqn. (2)

X_{rect}=2989.36(−1.98669+x)(−1.75709+x)(−1.6047+x)(1.79674−2.65596x+x²)(1.01583−1.90898x+x²)(0.476224−1.15508x+x²)(0.170155−0.495286x+x²)(0.0277489−0.0444861x+x²) Eqn. (3)

For V_{rect}=4.0V:

R_{rect}=−20017.4(−1.98953+x)(−1.7714+x)(−1.60307+x)(1.78598−2.65735x+x²)(0.989191−1.91453x+x²)(0.445237−1.17696x+x²)(0.148998−0.556037x+x²)(0.0276824−0.143845x+x²) Eqn. (4)

X_{rect}=1901.2(−1.99005+1·x)(−1.75862+1·x)(−1.64524+1·x)(1.89161−2.72018x+1·x̂2)(1.0835−1.9657x+1·x̂2)(0.512316−1.19657x+1·x̂2)(0.184643−0.521823x+1·x̂2)(0.0302315−0.0443056x+1·x̂2) Eqn. (5)

For V_{rect}=3.7V:

R_{rect}=−57030.8(−1.87994+x)(−1.67779+x)(−1.50783+x)(1.56865−2.49526x+x²)(0.856509−1.79463x+x²)(0.376423−1.10138x+x²)(0.121652−0.519154x+x²)(0.0216738−0.134583x+x²) Eqn. (6)

X_{rect}=5604.91(−1.88023+x)(−1.67184+x)(−1.53334+x)(1.6482−2.54668x+x²)(0.92963−1.8385x+x²)(0.429269−1.11971x+x²)(0.149856−0.492454x+x²)(0.0238891−0.0459037x+x²) Eqn. (7)

For V_{rect}=3.5V:

R_{rect}=−34300.8(−1.86854+x)(−1.67021+x)(−1.52956+x)(1.64112−2.54623x+x²)(0.91444−1.84378x+x²)(0.407585−1.13655x+x²)(0.132162−0.535464x+x²)(0.0235638−0.138568x+x²) Eqn. (8)

X_{rect}=3715.05(−1.86901+x)(−1.65829+x)(−1.56406+x)(1.71529−2.59248x+x²)(0.983776−1.88421x+x²)(0.459325−1.15576x+x²)(0.1607−0.515118x+x²)(0.0262806−0.0451413x+x²) Eqn. (9)

For V_{rect}=3.0V:

R_{rect}=34187.6(−1.88633+x)(−1.72702+x)(2.2859−3.02044x+x²)(1.49728−2.41325x+x²)(0.831376−1.7355x+x²)(0.366728−1.06543x+x²)(0.115174−0.499329x+x²)(0.0194268−0.128811x+x²) Eqn. (10)

X_{rect}=−4122.28(−1.88601+x)(−1.73113+x)(2.32775−3.04541x+x²)(1.54838−2.44406x+x²)(0.87905−1.76199x+x²)(0.403172−1.07659x+x²)(0.135962−0.482025x+x²)(0.0228602−0.0419783x+x²) Eqn. (11)

For V_{rect}=2.5V:

R_{rect}=−16.688(−2.17367+x)(4.30952−4.10117x+x²)(3.34389−3.45679x+x²)(2.21113−2.56548x+x²)(1.20815−1.60241x+x²)(0.499019−0.754243x+x²)(0.107341−0.173013x+x²) Eqn. (12)

X_{rect}=2.50601(−2.63795+x)(4.8023−4.36202x+x²)(3.76789−3.73931x+x²)(2.50454−2.84665x+x²)(1.36008−1.84499x+x²)(0.556745−0.914039x+x²)(0.134385−0.21722x+x²) Eqn. (13)

The transmitter, e.g., the transmitter 204, is configured to measure the static impedance of the receiver 410 and communicate this static impedance to the receiver 410, e.g., through one or more in-band and/or out-of-band signals. The static impedance communication signal(s) are received by the receiver 410, e.g., the antenna 412 and/or another antenna, and provided to the impedance estimator 440 via the transceiver 516. Also or alternatively, the receiver 410 may store the static impedance for the receiver for different transmitter types. The receiver 410 may communicate with the transmitter to determine the transmitter type, search for that transmitter type in a table transmitter types and static impedances, and if the transmitter type is found, provide the corresponding stored static impedance to the impedance estimator 440.

The impedance estimator 440 is configured to determine a value of the mutual inductance M between the receiver 410 and the transmitter 204. The impedance estimator 440 may estimate the mutual inductance M between the power receiving element 412 and the power transmitting element 214. For example, the impedance estimator 440 may use an indication of a transmitting element current I_{TX} provided by the transmitter 204 and received by the receiver 410, e.g., through in-band and/or out-of-band communication via the antenna 412 (and/or another antenna) and the transceiver 516. The impedance estimator 440 may use the rectified voltage V_{rect} to estimate the mutual inductance M as a function of the load 416. For example, the mutual inductance M may be determined according to Equation (2) below.

M=V_{rectNL}/(ω*I_{TX}) Eqn. (14)

In Equation (2), V_{rectNL} is the rectified voltage with no load.

The impedance estimator 440 is configured to evaluate a parameterized formulation for the impedance of the receiver 410 and the reflected impedance of the receiver 410 presented to the transmitter 204. The impedance estimator 440 may evaluate a parameterized expression for the front-end circuit 430 and the power receiving element 412 to determine an impedance for the front-end circuit 430 and the power receiving element 412 as discussed above. Thus, the controller 418 can determine a value for each of one or more dynamic parameters associated with the power-processing circuitry and determine, using the value for each of the one or more dynamic parameters, an estimated impedance of the receiver 410 presented to the transmitter 204. The impedance estimator 440 uses a value of each of one or more parameters provided by the controller 418, to the tuning circuit to tune the tuning circuit 434, to evaluate the expression for impedance of the front-end circuit 430 and the power receiving element 412. The impedance estimator 440 is further configured to determine an impedance for the rectifier 432, e.g., by evaluating a linearized model of the rectifier 432, which may be done by finding a resistance value and a reactance value on respective curves fit to a model. The impedance estimator 440 may find these values by looking up values in a look-up table based on appropriate parameters such as rectified DC voltage, DC load power, and one or more control variables, and possibly interpolating between values in the look-up table. The controller 418 is further configured to determine the resistance of the load 416 based on the rectified voltage V_{rect} and rectified current I_{rect} provided to the load 416, and to determine the mutual inductance M between the receiver 410 and the transmitter 204 as discussed above. The controller 418 is configured to use the impedances of the power receiving element 412, the front-end circuit 430, and the rectifier 432, the mutual inductance M, and load resistance, and the frequency of power received by the receiver 410 to determine the estimated impedance of the receiver 410 seen by the transmitter 204 by evaluating Eqn. (1).

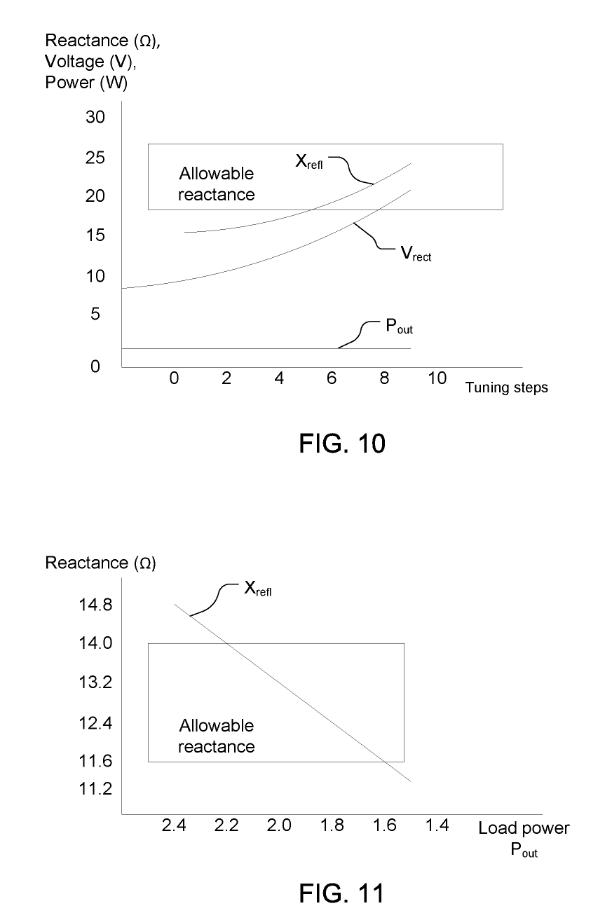

The controller 418 is configured to change one or more characteristics of the receiver 410 to change the reflected impedance of the receiver 410 seen by the transmitter 204. The controller 418 is configured to change the value of one or more dynamic parameters to affect the operation of the receiver 410 and the reflected impedance presented to the transmitter 204. For example, the controller 418 can change the series-connected capacitance value C_{S}, the parallel-connected capacitance value C_{P}, and/or the phase and/or duty cycle of the rectifier 432 to affect the DC rectified voltage V_{rect}. Preferably, the controller 418 tunes the receiver 410, e.g., by adjusting the parameter values input to the tuning circuit 434, while maintaining power delivered to the load 416 relatively constant (e.g., within 5% of an average power). For example, referring also to FIG. 10, the controller 418 may be configured to adjust tuning, which changes the DC rectified voltage V_{rect} while keeping power Pₒᵤₜ to the load 416 constant, resulting in a change in reflected reactance X_{refl} presented to the transmitter 204. The tuning is performed in tuning steps (e.g., different rectifier phases). The controller 418 may also or alternatively change an amount of power delivered to the load 416, e.g., to decrease (i.e., throttle back) the power to the load 416, for example by lowering a current limit of a battery charger. For example, referring also to FIG. 11, the controller 418 may be configured to decrease the power Pₒᵤₜ to the load 416 to affect the reflected impedance. The controller 418 may be configured to decrease the power Pₒᵤₜ to the load 416, e.g., in response to a change in the reflected impedance being desired even after the available impedance-tuning parameters (e.g., C_{S}, C_{P}, rectifier phase, rectifier duty cycle) having been manipulated (i.e., without the reflected impedance reaching a desired value). That is, if a limit of tuning has been reached without adjusting the power to the load 416 but the reflected impedance is still not within an acceptable (e.g., specified) range, then the controller 418 may adjust the power provided to the load 416 to affect the reflected impedance. The controller 418 may also or alternatively be configured to change an amount of power used by the rectifier 432 to affect the reflected impedance, e.g., to have the rectifier 432 use more power to increase the reflected reactance X_{refl}, for example by adjusting the phase and/or duty cycle of switches of the rectifier 432.

The controller 418 may be configured to adjust the operation of the receiver 410 to try to cause the reflected impedance presented to the transmitter 204 to be in an acceptable range, e.g., to move the reflected impedance toward or within the acceptable range. A range of acceptable impedance may include a range of acceptable resistance and/or a range of acceptable reactance. The controller 418 may store acceptable impedance information in the memory 512, e.g., with specified impedance ranges and corresponding transmitters (e.g., transmitter types). Also or alternatively, the controller 418 may be configured to receive an indication of a specified, acceptable impedance range from the transmitter 204 wirelessly through in-band and/or out-of-band communication. The indication of the specified impedance range provided by the transmitter 204 may vary over time, e.g., as one or more receivers are brought into range of the transmitter 204 and/or taken out of range of the transmitter 204 and/or as the quantity of receivers changes and/or as the types of receivers change and/or as the individual impedance of one or more of the receivers change and/or as the proximity of one or more of the receivers relative to the transmitter changes (as this may affect the impedance seen by the transmitter due to a receiver even if the impedance of that receiver is constant).

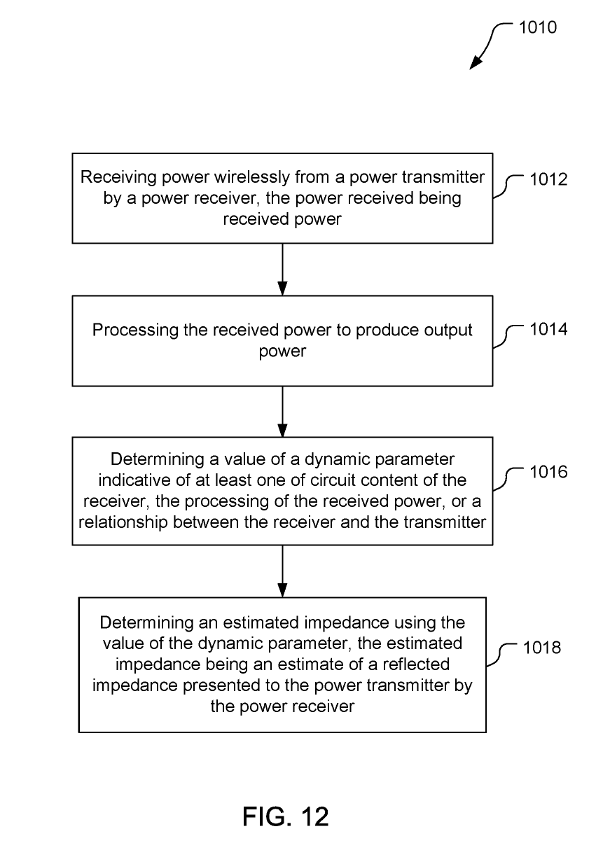

Referring to FIG. 12, with further reference to FIGS. 1-9, a method 1010 of estimating impedance of a wireless power receiver includes the stages shown. The method 1010 is, however, an example only and not limiting. The method 1010 may be altered, e.g., by having stages added, removed, rearranged, combined, performed concurrently, and/or having single stages split into multiple stages.

At stage 1012, the method 1010 includes receiving power wirelessly from a transmitter by a receiver, the power received being received power. For example, the transmitter 204 sends power to the receiver 410 (and possibly other receivers) and the receiver 410 receives at least some of the power sent by the transmitter 204. The power receiving element 412, e.g., a coil antenna or other form of antenna, receives power from the transmitter 204, e.g., inductively.

At stage 1014, the method 1010 includes processing the received power to produce output power. For example, the processing includes transducing and transmission by the power receiving element 412 and further processing by the power-processing circuitry 414. The power-processing circuitry 414 includes tuning and impedance matching by the tuning circuit 434 as discussed above with respect to the front-end circuit 232, filtering by the EMI filter 436, and voltage rectification by the rectifier 432. The processing by the power-processing circuitry provides output power Pₒᵤₜ (FIG. 10) with components of DC rectified voltage V_{rect} and corresponding DC rectified current I_{rect}.

At stage 1016, the method 1010 includes determining a value of a dynamic parameter indicative of at least one of circuit content of the receiver, the processing of the received power, or a relationship between the receiver and the transmitter. For example, the impedance estimator 440 can access or monitor a value of a series-connected capacitance C_{S} indicated by the controller 418, access and/or monitor a value of a parallel-connected capacitance C_{P} indicated by the controller 418, access and/or monitor a phase and/or a duty cycles indicated by the controller 418, receive an indication of the DC rectified voltage V_{rect} and an indication of the corresponding DC rectified current I_{rect}. Also or alternatively, the impedance estimator 440 may determine one or more values indicative of a dynamic condition of the load 416. As further examples, the impedance estimator 440 may determine a value of at least one of a frequency of the received power, a mutual coupling of the receiver 410 and the transmitter, or a dynamic impedance of the receiver 410, or a combination thereof. To determine the value of the dynamic impedance of the receiver 410, the impedance estimator 440 may calculate the dynamic impedance of the receiver using a linearized model (e.g., the model 1200) of power-processing circuitry of the receiver 410.

At stage 1018, the method 1010 includes determining an estimated impedance using the value of the dynamic parameter, the estimated impedance being an estimate of a reflected impedance presented to the transmitter by the receiver. If at stage 1016 multiple values, corresponding to multiple dynamic parameters, were determined, then at stage 1018 one or more of these values may be used to determine the estimated impedance. For example, the impedance estimator 440 of the controller 418 evaluates a model of the receiver 410 by inserting the value(s) of the dynamic parameter(s) into a model of the power-processing circuitry 414 (e.g., one or more linearized equations and/or circuit simulations) to determine the resistance R_{L} of the load 416 and the impedance Z_{T} of the receiver circuit 434. The controller 418 further determines a value of the mutual coupling M and determines the estimated impedance by inserting into, and evaluating, Equation (1) using the determined values of Zₛ, R_{L}, Z_{T}, and M, and the frequency f of the transmission power.

The controller 418 uses the results of the estimated impedance, along with information regarding acceptable impedance, to adjust operation of the receiver to try to provide a reflected impedance to the transmitter 204 that is acceptable, e.g., within a specified impedance range. The controller 418 may change one or more parameter values to change the estimated impedance toward (or to retain the estimated impedance in) the specified impedance range. For example, the controller 418 may determine a type of the transmitter and look up an acceptable reactance range for that transmitter and adjust one or more dynamic parameter values to try to keep an estimated reflected reactance presented to the transmitter within the looked-up acceptable range. The looked-up acceptable range may be pre-specified (i.e., specified before interaction with the transmitter 204 by the receiver 410). Also or alternatively, the transmitter 204 may send a specified reactance range to the receiver 410, and may adjust this specified reactance, e.g., as one or more other receivers begin, end, or change the reflected impedance seen by the transmitter 204 corresponding to the other receiver(s) and thus affect the total impedance seen by the transmitter 204. The receiver 410 receives the specified impedance range, and to try to keep the reflected impedance within a specified impedance range, the controller 418 changes, for example, a value of one or more variable reactances (e.g., a value of the series-connected capacitance value C_{S} and/or a value of the parallel-connected capacitance value C_{P} and/or the use of a switched capacitor and/or the use of a switched inductor).

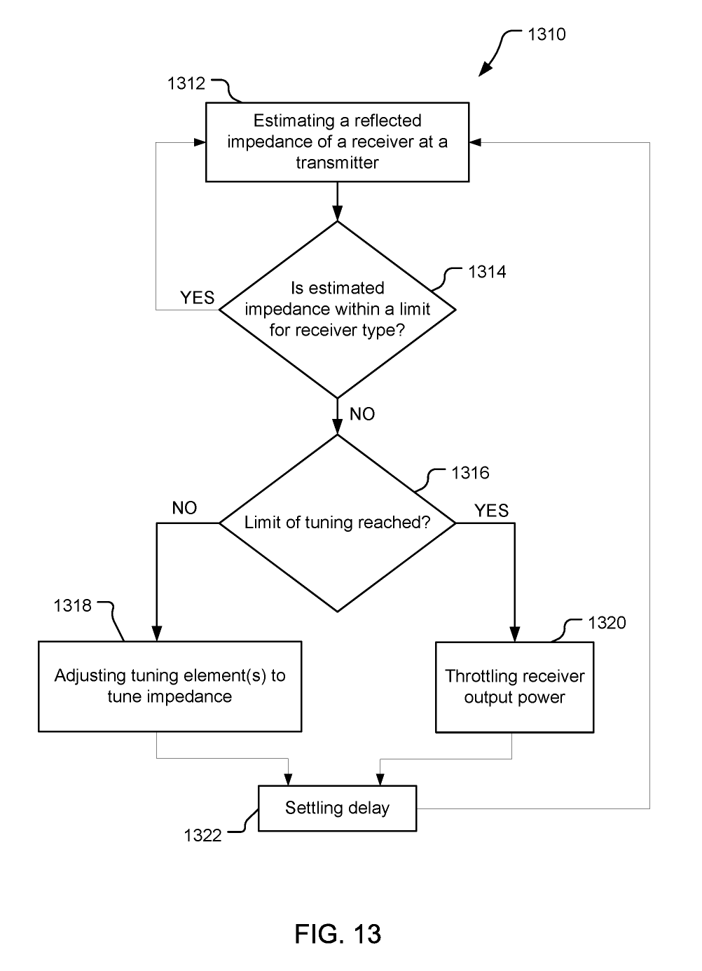

Referring to FIG. 13, with further reference to FIGS. 1-9, a method 1310 includes the stages shown. The method 1310 is, however, an example only and not limiting. The method 1310 may be altered, e.g., by having stages added, removed, rearranged, combined, performed concurrently, and/or having single stages split into multiple stages.

At stage 1312, the method 1310 includes estimating a reflected impedance of a receiver at a transmitter. For example, the processor 510 estimates the reflected impedance of the receiver 410 seen by the transmitter 204, e.g., using Equation (1). The processor 510 determines an acceptable range of the estimated reflected impedance, i.e., an acceptable impedance range for the receiver 410. As discussed above, the range may be predetermined, e.g., based on a category of the receiver 410, or may be determined and provided by the transmitter 204 to the receiver 410, e.g., based on a number of devices presently charged by the transmitter 204.

At stage 1314, the method 1310 includes an inquiry of whether the estimated impedance is within a limit for a receiver type. For example, the processor 510 analyzes a look-up table in the memory 512 that includes receiver types and corresponding impedance limits (e.g., an acceptable impedance range) to find a receiver type corresponding to the receiver 410, and consequently a corresponding acceptable impedance range. The processor 510 determines whether the impedance determined in stage 1312 is within the acceptable range found from the look-up table (or otherwise found/determined). If the determined impedance is within the acceptable range, then the method 1310 returns to stage 1312 for repeated estimations of the reflected impedance. If the determined impedance is not within the acceptable range, then the method 1310 proceeds to stage 1316.

At stage 1316, the method 1310 includes an inquiry of whether a limit of impedance tuning has been reached. If the limit of impedance tuning has not been reached, then the method 1310 proceeds to stage 1318 where the method 1310 includes adjusting tuning element(s) to tune the impedance. For example, the processor 510 can cause changes in one or more capacitance values of the tuning circuit 434 and or phase and/or duty cycle of the rectifier 432 to change the impedance to be closer to or within the acceptable impedance range. If at stage 1316 it is determined that the limit of impedance tuning has not been reached, then the method 1310 proceeds to stage 1320 where the method 1310 includes throttling receiver output power.

At stage 1322, the method 1310 includes waiting for a settling delay time. For example, once one or more tuning adjustments are made, or power is throttled, a settling delay time is allowed to pass so that the effects of the respective action(s) may reach a steady state. After the settling delay time has passed, the method 1310 returns to stage 1312 for estimating the reflected receiver impedance.

Other Considerations

Other examples and implementations are within the scope and spirit of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, “or” as used in a list of items prefaced by “at least one of” or prefaced by “one or more of” indicates a disjunctive list such that, for example, a list of “at least one of A, B, or C,” or a list of “one or more of A, B, or C” means A or B or C or AB or AC or BC or ABC (i.e., A and B and C), or combinations with more than one feature (e.g., AA, AAB, ABBC, etc.).

As used herein, unless otherwise stated, a statement that a function or operation is “based on” an item or condition means that the function or operation is based on the stated item or condition and may be based on one or more items and/or conditions in addition to the stated item or condition.

Further, an indication that information is sent or transmitted, or a statement of sending or transmitting information, “to” an entity does not require completion of the communication. Such indications or statements include situations where the information is conveyed from a sending entity but does not reach an intended recipient of the information. The intended recipient, even if not actually receiving the information, may still be referred to as a receiving entity, e.g., a receiving execution environment. Further, an entity that is configured to send or transmit information “to” an intended recipient is not required to be configured to complete the delivery of the information to the intended recipient. For example, the entity may provide the information, with an indication of the intended recipient, to another entity that is capable of forwarding the information along with an indication of the intended recipient.

Substantial variations may be made in accordance with specific requirements. For example, customized hardware might also be used, and/or particular elements might be implemented in hardware, software (including portable software, such as applets, etc.), or both. Further, connection to other computing devices such as network input/output devices may be employed.

The methods, systems, and devices discussed above are examples. Various configurations may omit, substitute, or add various procedures or components as appropriate. For instance, in alternative configurations, the methods may be performed in an order different from that described, and that various steps may be added, omitted, or combined. Also, features described with respect to certain configurations may be combined in various other configurations. Different aspects and elements of the configurations may be combined in a similar manner. Also, technology evolves and, thus, many of the elements are examples and do not limit the scope of the disclosure or claims.

Specific details are given in the description to provide a thorough understanding of example configurations (including implementations). However, configurations may be practiced without these specific details. For example, well-known circuits, structures, and techniques have been shown without unnecessary detail in order to avoid obscuring the configurations. This description provides example configurations only, and does not limit the scope, applicability, or configurations of the claims. Rather, the preceding description of the configurations provides a description for implementing described techniques. Various changes may be made in the function and arrangement of elements without departing from the spirit or scope of the disclosure.

Also, configurations may be described as a process which is depicted as a flow diagram or block diagram. Although each may describe the operations as a sequential process, many of the operations can be performed in parallel or concurrently. In addition, the order of the operations may be rearranged. A process may have additional stages or functions not included in the figure. Furthermore, examples of the methods may be implemented by hardware, software, firmware, middleware, microcode, hardware description languages, or any combination thereof. When implemented in software, firmware, middleware, or microcode, the program code or code segments to perform the tasks may be stored in a non-transitory computer-readable medium such as a storage medium. Processors may perform the described tasks.

Components, functional or otherwise, shown in the figures and/or discussed herein as being coupled, connected, or communicating with each other are operably coupled. That is, they may be directly or indirectly, wired or wirelessly, connected to enable signal flow between them.

Having described several example configurations, various modifications, alternative constructions, and equivalents may be used without departing from the spirit of the disclosure. For example, the above elements may be components of a larger system, wherein other rules may take precedence over or otherwise modify the application of the invention. Also, a number of operations may be undertaken before, during, or after the above elements are considered. Accordingly, the above description does not bound the scope of the claims.

Further, more than one invention may be disclosed.

1. A wireless power receiver comprising:
a power-receiving antenna configured to receive power wirelessly from a transmitter;
power-processing circuitry that is coupled to the power-receiving antenna to receive power from the power-receiving antenna and that is configured to process the power received from the power-receiving antenna; and
a controller communicatively coupled to the power-processing circuitry and configured to:
determine a value of a dynamic parameter indicative of at least one of content of the power-processing circuitry, operation of the power-processing circuitry, or a relationship between the receiver and the transmitter; and
determine an estimated impedance using the value of the dynamic parameter, the estimated impedance being an estimate of at least a portion of reflected impedance presented to the transmitter by the receiver.

2. The receiver of claim 1, wherein the controller is configured to determine the estimated impedance by using the value of the dynamic parameter in a model of the power-processing circuitry.

3. The receiver of claim 2, wherein the model is a linearized model of the power-processing circuitry.

4. The receiver of claim 3, wherein the power-processing circuitry includes a rectifier and the linearized model of the power-processing circuitry includes a linearized model of the rectifier.

5. The receiver of claim 1, wherein the controller is configured to determine a value of at least one of a plurality of dynamic parameters including a frequency of power received by the antenna, a mutual coupling of the receiver and a transmitter, or a dynamic impedance of the receiver, or a combination thereof, and to determine the estimated impedance using the value of the at least one of the plurality of dynamic parameters.

6. The receiver of claim 5, wherein the controller is configured to calculate the value of the dynamic impedance using a linearized model of the power-processing circuitry.

7. The receiver of claim 1, wherein the controller is further configured to change, in response to the estimated impedance being undesirable, the power-processing circuitry to change the estimated impedance toward a specified impedance range for the transmitter.

8. The receiver of claim 7, wherein the controller is configured to cause the power-processing circuitry to change a reactance value of a variable reactance element to change the estimated impedance toward the specified impedance range for the transmitter.

9. The receiver of claim 7, wherein the controller is configured to cause the power-processing circuitry to decrease an amount of power provided to a load by the power-processing circuitry to change the estimated impedance toward the specified impedance range for the transmitter.

10. The receiver of claim 7, wherein the controller is configured to cause the power-processing circuitry to increase power consumption of the power-processing circuitry to change the estimated impedance toward the specified impedance range for the transmitter.

11. The receiver of claim 7, wherein the controller is further configured to receive wirelessly, from the transmitter via the power-receiving antenna or a communication antenna, an indication of the specified range for the transmitter.

12. A method of estimating impedance of a wireless power receiver, the method comprising:
receiving power wirelessly from a transmitter by a receiver, the power received being received power;
processing the received power to produce output power;
determining a value of a dynamic parameter indicative of at least one of circuit content of the receiver, the processing of the received power, or a relationship between the receiver and the transmitter; and
determining an estimated impedance using the value of the dynamic parameter, the estimated impedance being an estimate of a reflected impedance presented to the transmitter by the receiver.

13. The method of claim 12, wherein determining the estimated impedance comprises using the value of the dynamic parameter in a model of power-processing circuitry of the receiver.

14. The method of claim 12, wherein determining the value of the dynamic parameter comprises determining a value of at least one of a frequency of the received power, a mutual coupling of the receiver and the transmitter, or a dynamic impedance of the receiver, or a combination thereof, and wherein determining the estimated impedance uses the value of the at least one of the plurality of dynamic parameters.

15. The method of claim 12, wherein determining the value of the dynamic impedance of the receiver comprises calculating the dynamic impedance of the receiver using a linearized model of power-processing circuitry of the receiver.

16. The method of claim 12, further comprising changing the processing of the received power to change the estimated impedance toward a specified impedance range for the transmitter.

17. The method of claim 16, wherein the value of the dynamic parameter is a reactance value of a variable reactance element, and changing the processing comprises changing the reactance value of the variable reactance element change the estimated impedance toward the specified impedance range for the transmitter.

18. The method of claim 16, wherein changing the processing comprises decreasing an amount of power provided to a load to change the estimated impedance toward the specified range for the transmitter.

19. The method of claim 16, further comprising receiving wirelessly, from the transmitter, an indication of the specified range for the transmitter.

20. A non-transitory, processor-readable storage medium comprising processor-readable instructions configured to cause a processor to:
determine a value of a dynamic parameter indicative of at least one of content of a receiver, operation of the receiver, or a relationship of the receiver and a transmitter; and
determine an estimated impedance using the value of the dynamic parameter, the estimated impedance being an estimate of a reflected impedance presented to the transmitter by the receiver.

21. The storage medium of claim 20, wherein the instructions configured to cause the processor to determine the estimated impedance are configured to cause the processor to use the value of the dynamic parameter in a model of power-processing circuitry.

22. The storage medium of claim 20, further comprising instructions configured to cause the processor to change the value of the dynamic parameter to try to cause the estimated impedance to be within a specified range for the transmitter.

23. A wireless power receiver comprising:
power-receiving means for receiving power wirelessly from a transmitter;
processing means, coupled to the power-receiving, for processing power received from the power-receiving means to produce output power;
means for determining a value of a dynamic parameter indicative of at least one of content of the processing means, operation of the processing means, or a relationship between the receiver and the transmitter; and
means for determining an estimated impedance using the value of the dynamic parameter, the estimated impedance being an estimate of a reflected impedance presented to the transmitter by the receiver.

24. The receiver of claim 23, wherein the means for determining the estimated impedance are for using the value of the dynamic parameter in a model of power-processing circuitry.

25. The receiver of claim 23, wherein the means for determining the value of the dynamic parameter include means for determining a value of at least one of a plurality of dynamic parameters including a frequency of the received power, a mutual coupling of the receiver and the transmitter, or a dynamic impedance of the receiver, or a combination thereof, and wherein the means for determining the estimated impedance are for determining the estimated impedance using the value of the at least one of the plurality of dynamic parameters.

26. The receiver of claim 25, wherein the means for determining the value of the dynamic impedance of the receiver are for calculating the dynamic impedance of the receiver using a linearized model of power-processing circuitry of the receiver.

27. The receiver of claim 23, further comprising impedance-changing means, communicatively coupled to the processing means, for causing the processing means to change the processing of the power received from the power-receiving means to try to cause the estimated impedance to be within a specified range for the transmitter.

28. The receiver of claim 27, wherein the impedance-changing means are for changing a reactance value of a variable reactance element to try to cause the estimated impedance to be within the specified range for the transmitter.

29. The receiver of claim 27, wherein the impedance-changing means are for decreasing the output power to try to cause the estimated impedance to be within the specified range for the transmitter.

30. The receiver of claim 27, further comprising means for wirelessly receiving, from the transmitter, an indication of the specified range for the transmitter.
